(19) United States
(12) Patent Application Publication
(10) Pub. No.: US 2025/0040383 A1
(43) Pub. Date: Jan. 30, 2025

(54) DISPLAY PANEL AND DISPLAY APPARATUS

(71) Applicant: Hubei Yangtze Industrial Innovation Center Of Advanced Display Co., Ltd., Wuhan (CN)

(72) Inventors: Qin YUE, Wuhan (CN); Yangzhao MA, Wuhan (CN)

(21) Appl. No.: 18/916,763

(22) Filed: Oct. 16, 2024

(30) Foreign Application Priority Data
Oct. 24, 2023 (CN) 202311388481.3

(51) Int. Cl. H10K 59/131; H10K 59/122

(52) U.S. Cl. CPC H10K 59/131; H10K 59/122

(57) ABSTRACT

A display panel and a display apparatus are provided. The display panel includes a substrate, signal lines, a pixel definition layer having a first aperture corresponding to the first light-emitting element, and light-emitting elements at least including a first light-emitting element. The signal lines at least include a first signal line including a first portion and a second signal line including a second portion. An orthographic projection of the first aperture on the plane of the substrate has a first center line, and the orthographic projection of the first portion on the plane of the substrate and the orthographic projection of the second portion on the plane of the substrate are symmetrical about the first center line.

### CROSS-REFERENCE TO RELATED APPLICATION

The present application claims priority to Chinese Patent Application No. 202311388481.3, filed on Oct. 24, 2023, the content of which is incorporated herein by reference in its entirety.

### TECHNICAL FIELD

The present disclosure generally relates to the field of display technologies, and in particular to a display panel and a display apparatus.

### BACKGROUND

Organic light-emitting diode (OLED) display panels are widely applied due to their characteristics such as self-luminescence, fast response speed, and flexible display.

At present, when the OLED display panel is viewed at different viewing angles, there will be a phenomenon that the color cast conditions in the four orientations including up, down, left and right in the front view direction of the OLED display panel are inconsistent, that is, the OLED display panel has a four-orientation color cast problem.

### SUMMARY

In a first aspect, embodiments of the present disclosure provide a display panel. The display panel includes a substrate, an array layer including a plurality of signal lines, and a display layer located on a side of the array layer away from the substrate. The display layer includes a pixel definition layer and light-emitting elements. One of the light-emitting elements includes a first electrode, a light-emitting layer and a second electrode that are stacked. The pixel definition layer is located on a side of the first electrode away from the substrate. The pixel definition layer has an aperture exposing at least a part of the first electrode. The light-emitting elements at least include a first light-emitting element. The pixel definition layer has a first aperture corresponding to the first light-emitting element. The plurality of signal lines at least include a first signal line and a second signal line. The first signal line includes a first portion. An orthographic projection of the first portion on a plane of the substrate is within the range of the orthographic projection of the first aperture on the plane of the substrate. The second signal line includes a second portion. An orthographic projection of the second portion on the plane of the substrate is located in the orthographic projection of the first aperture on the plane of the substrate. The orthographic projection of the first aperture on the plane of the substrate has a first center line, and the orthographic projection of the first portion on the plane of the substrate and the orthographic projection of the second portion on the plane of the substrate are symmetrical about the first center line.

In a second aspect, embodiments of the present disclosure provide a display apparatus including a display panel. The display panel includes a substrate, an array layer including a plurality of signal lines, and a display layer located on a side of the array layer away from the substrate. The display layer includes a pixel definition layer and light-emitting elements. One of the light-emitting elements includes a first electrode, a light-emitting layer and a second electrode that are stacked. The pixel definition layer is located on a side of the first electrode away from the substrate. The pixel definition layer has an aperture exposing at least a part of the first electrode. The light-emitting elements at least include a first light-emitting clement. The pixel definition layer has a first aperture corresponding to the first light-emitting clement. The plurality of signal lines at least include a first signal line and a second signal line. The first signal line includes a first portion. An orthographic projection of the first portion on a plane of the substrate is within the range of the orthographic projection of the first aperture on the plane of the substrate. The second signal line includes a second portion. An orthographic projection of the second portion on the plane of the substrate is located in the orthographic projection of the first aperture on the plane of the substrate. The orthographic projection of the first aperture on the plane of the substrate has a first center line, and the orthographic projection of the first portion on the plane of the substrate and the orthographic projection of the second portion on the plane of the substrate are symmetrical about the first center line.

### BRIEF DESCRIPTION OF DRAWINGS

In order to describe the technical solutions in the embodiments of the present disclosure more clearly, the drawings which are needed in the description of the embodiments will be briefly introduced as follows, obviously, the drawings in the following description are only some of the embodiments of the present disclosure, and for those of ordinarily skilled in the art, other drawings can also be obtained in accordance with these drawings without any creative effort.

FIG. 1 is a partially enlarged view of a display panel according to some

embodiments of the present disclosure;

FIG. 2 is an equivalent circuit diagram of a sub-pixel corresponding to FIG. 1 according to an embodiment of the present disclosure;

FIG. 3 is a schematic cross-sectional view showing a display panel according to an embodiment of the present disclosure;

FIG. 4 is a partially enlarged view of a display panel according to an embodiment of the present disclosure;

FIG. 5 is a partially enlarged view of a display panel according to an embodiment of the present disclosure;

FIG. 6 is a partially enlarged view of a display panel according to an embodiment of the present disclosure;

FIG. 7 is a partially enlarged view of a display panel according to an embodiment of the present disclosure;

FIG. 8 is a schematic sectional view of a display panel according to an embodiment of the present disclosure;

FIG. 9 is a partially enlarged view of a display panel according to an embodiment of the present disclosure;

FIG. 10 is a partially enlarged view of another display panel according to some embodiments of the present disclosure;

FIG. 11 is a schematic cross-sectional view of a display panel according to an embodiment of the present disclosure;

FIG. 12 is a partially enlarged view of a display panel according to an embodiment of the present disclosure; and

FIG. 13 is a schematic diagram of a display apparatus according to an embodiment of the present disclosure.

### DESCRIPTION OF EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the present disclosure, not intended to limit the present disclosure. In order to better understand the technical solutions of the present disclosure, embodiments of the present disclosure are described in detail as follows with reference to the accompanying drawings.

The described embodiments are merely some but not all of the embodiments of the present disclosure. All other embodiments obtained by a person of ordinary skill in the art d on the embodiments of the present disclosure shall fall within the scope of the present disclosure.

The terms used in the embodiments of the present disclosure are for the purpose of describing specific embodiments only, and are not intended to limit the present disclosure. As used in the embodiments and the appended claims of the present disclosure, the singular forms of “a/an”, “the”, and “said” are intended to include plural forms, unless otherwise clearly specified by the context.

It should be understood that the term “and/or” used herein is merely an association relationship describing associated objects, indicating that there may be three relationships, for example, A and/or B may indicate that three cases, i.e., A existing individually, A and B existing simultaneously, B existing individually. In addition, the character “/” herein generally indicates an “or” relationship between the associated objects.

In the process of implementing the embodiments of the present disclosure, the applicants have found that the flatness of the surface of the first electrode in the light-emitting element may cause a difference in light emitted from the light-emitting element to different directions, and cause a difference in brightness of the light-emitting element when observed at different viewing angles, thereby causing a problem of viewing angle color cast when sub-pixels of different colors in the display panel are displayed in cooperation, for example, a problem of four-orientation color cast with inconsistent color cast when the display panel is observed at four ways including up, down, left and right relative to a front viewing angle of the display panel.

In view of this, in some embodiments of the present disclosure, the signal lines overlapped with the first electrodes in the array layer are designed, and the first signal lines and the second signal lines overlap with the first electrodes are symmetrical about the center line of the aperture of the pixel definition layer, so that the brightness difference of the light-emitting elements overlapped with the first signal lines and the second signal lines at different viewing angles is reduced, thereby improving the four-orientation color cast problem of the display panel and improving the display effect.

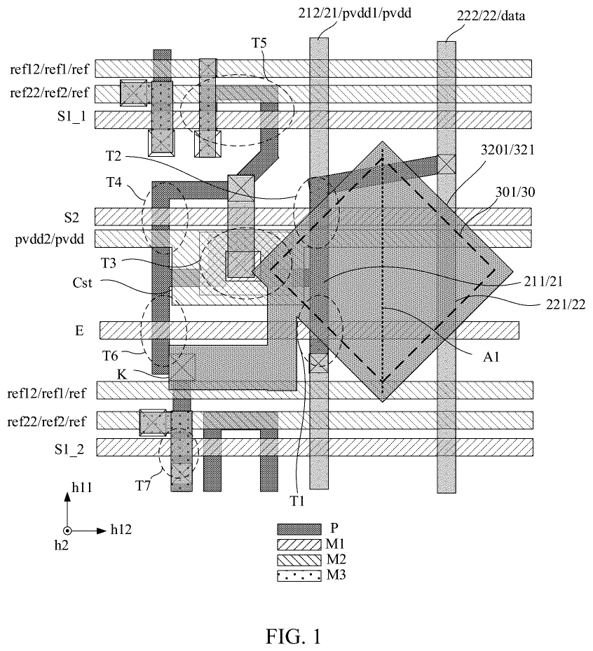

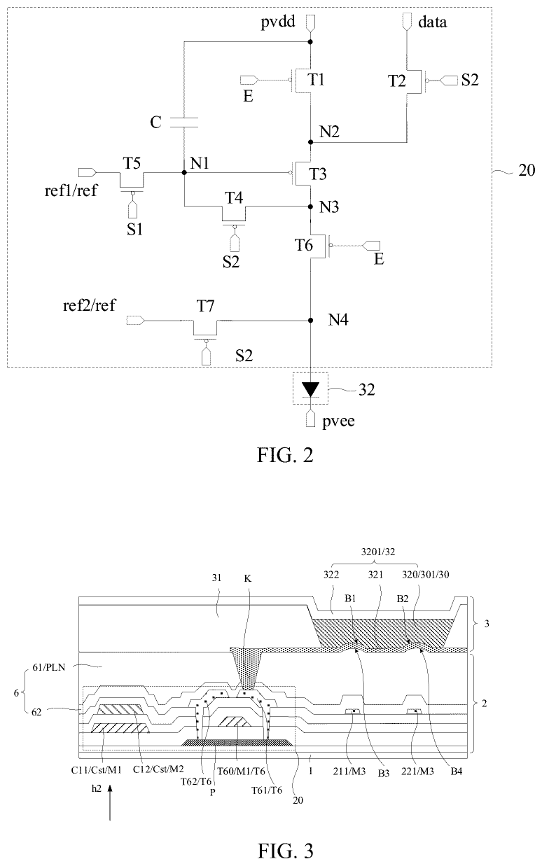

In some embodiments of the present disclosure, the embodiments of the present disclosure provides a display panel. The display panel includes a plurality of sub-pixels. Each sub-pixel includes a light-emitting element and a pixel driving circuit electrically connected to each other. FIG. 1 is a partial enlarged schematic diagram of a display panel according to an embodiment of the present disclosure, FIG. 2 is an equivalent circuit diagram of a sub-pixel corresponding to FIG. 1 according to an embodiment of the present disclosure, FIG. 3 is a cross-sectional schematic diagram of a display panel according to an embodiment of the present disclosure. As shown in FIG. 1, FIG. 2 and FIG. 3, the display panel includes a substrate 1, an array layer 2 located on a side of the substrate 1, and a display layer 3 located on a side of the array layer 2 away from the substrate 1.

The array layer 2 includes a pixel driving circuit 20 and a plurality of signal lines electrically connected to the pixel driving circuit 20. Referring to FIG. 3, the display layer 3 includes a pixel definition layer 31 and a light-emitting element 32. The light-emitting element 32 includes a first electrode 321, a light-emitting layer 320 and a second electrode 322 which are stacked. The pixel definition layer 31 is located on a side of the first electrode 321 away from the substrate 1. The pixel definition layer 31 has an aperture 30 exposing at least a part of the first electrode 321. The light-emitting layer 320 is at least partially located in the aperture 30. In some embodiments of the present disclosure, the first electrode 321 includes an anode, and the second electrode 322 includes a cathode.

In some embodiments of the present disclosure, as shown in FIG. 1, the light-emitting element 32 at least includes a first light-emitting element 3201, and the pixel definition layer 31 has a first aperture 301 corresponding to the first light-emitting element 3201. That is, the first aperture 301 exposes at least a part of the first electrode 321 of the first light-emitting element 3201. The signal lines include at least a first signal line 21 and a second signal line 22. The first signal line 21 includes a first portion 211, and an orthographic projection of the first portion 211 on a plane of the substrate 1 is located in an orthographic projection of the first aperture 301 on the plane of the substrate 1. The second signal line 22 includes a second portion 221, and an orthographic projection of the second portion 221 on the plane of the substrate 1 is located in an orthographic projection of the first aperture 301 on the plane of the substrate 1.

As shown in FIG. 1, the orthographic projection of the first aperture 301 on the plane of the substrate 1 has a first center line A1, and the orthographic projection of the first portion 211 on the plane of the substrate 1 and the orthographic projection of the second portion 221 on the plane of the substrate 1 are symmetrical about the first center line A1. FIG. 1 illustrates that the first center line A1 extends along the first direction h11. As shown in FIG. 1, the first portion 211 and the second portion 221 both extend along the first direction h11, a distance between the first portion 211 and the first center line A1 is equal to a distance between the second portion 221 and the first center line A1, and a width of the first portion 211 is equal to a width of the second portion 221. The width direction of the first portion 211 is perpendicular to the first direction h11.

As shown in FIG. 3, a distance between a position of the first electrode 321 corresponding to the first signal line 21 and the substrate 1 is relatively large compared to distances between other positions and the substrate 1, and a distance between a position of the first electrode 321 corresponding to the second signal line 22 and the substrate 1 is also relatively large compared to distances between other positions and the substrate 1. That is, a first convex B1 will be formed in the first electrode 321 at a position corresponding to the first signal line 21, and a second convex B2 will be formed in the first electrode 321 at a position corresponding to the second signal line 22. In some embodiments of the present disclosure, the orthographic projection of the first portion 211 on the plane of the substrate 1 and the orthographic projection of the second portion 221 on the plane of the substrate 1 are symmetrical about the first center line A1, so that the first convex B1 and the second convex B2 are symmetric about the first center line A1, so that when the display panel is viewed at a large viewing angle located at two sides of the first center line A1, the brightness of the first light-emitting element 3201 tends to be consistent, and the color cast degree of the display panel at different viewing angles tends to be consistent.

It should be noted that the shapes of the first convex B1 and the second convex B2 shown in FIG. 3 are merely illustrative, and are not intended to limit the embodiments of the present disclosure.

In some embodiments of the present disclosure, the pixel driving circuit 20 includes a storage capacitor and a plurality of thin film transistors. In some embodiments of the present disclosure, as shown in FIG. 1 and FIG. 2, the pixel driving circuit 20 includes a first transistor T1, a second transistor T2, a third transistor T3, a fourth transistor T4, a fifth transistor T5, a sixth transistor T6, a seventh transistor T7 and a storage capacitor Cst.

The signal line includes a data line data, a first power supply voltage line pvdd, a second power supply voltage line pvee (not shown in FIG. 1), a reference voltage line ref, a first scan line S1, a second scan line S2, and a light-emitting control line E. As shown in FIG. 1, the data line data extends along the first direction h11. The first scan line S1, the second scan line S2, and the light-emitting control line E all extend along the second direction h12, and the first direction h11 intersects the second direction h12. The first power supply voltage line pvdd includes a first sub-power supply voltage line pvdd1 extending in the first direction h11 and a second sub-power supply voltage line pvdd2 extending in the second direction h12. The first sub-power supply voltage line pvdd1 is electrically connected to the second sub-power supply voltage line pvdd2.

FIG. 1 shows two first scan lines labeled as S1_1 and S1_2, respectively, signals transmitted by the first scan line S1_2 and the second scan line S2 may be the same. In some embodiments of the present disclosure, the display panel further includes a scan driving circuit, the scan driving circuit includes a plurality of cascaded scan driving units, and the i^{th} scan driving unit may be electrically connected to the second scan line S2_i and the first scan line S1_i+1, respectively.

An operating process of the pixel driving circuit 20 includes a reset phase, a charging phase and a light-emitting phase. In the reset phase, the fifth transistor T5 is turned on under the action of the first scan line S1_1, and the reference voltage REF provided by the reference voltage line ref resets the first node NI through the fifth transistor T5. In the charging phase, the second transistor T2 and the fourth transistor T4 are turned on under the action of the second scan line S2, the seventh transistor T7 is turned on under the action of the first scan line S1_2, and the data voltage DATA provided by the data line data is written into the second node N2 through the second transistor T2. In this phase, the third transistor T3 is turned on. The potential of the first node N1 changes continuously until the potential V_{N1} of the first node N1 changes to V_{N1}=V_{DATA}−|Vₜₕ|, and Vₜₕ is the threshold voltage of the third transistor T3. The reference voltage REF resets the fourth node N4 through the seventh transistor T7. In the light-emitting stage, the first transistor T1, the sixth transistor T6 and the third transistor T3 are turned on, and the light-emitting element 32 is lightened.

In some embodiments of the present disclosure, both the fifth transistor T5 and the seventh transistor T7 receive the reference voltage REF provided by the reference voltage line ref. In some embodiments of the present disclosure, as shown in FIG. 1 and FIG. 2, the reference voltage line ref includes a first reference voltage line ref1 transmitting the first reference voltage REF1 and a second reference voltage line ref2 transmitting the second reference voltage REF2. The first reference voltage line ref1 is electrically connected to the fifth transistor T5 to reset the first node N1 by using the first reference voltage REF1. The second reference voltage line ref2 is electrically connected to the seventh transistor T7 to reset the fourth node N4 by using the second reference voltage REF2. The first reference voltage REF1 and the second reference voltage REF2 have different voltage values.

In some embodiments of the present disclosure, as shown in FIG. 1, in some embodiments of the present disclosure, the first reference voltage line ref1 may be configured to include a first reference voltage sub-line ref12 extending in the second direction h12, and the second reference voltage line ref2 may be configured to include a second reference voltage sub-line ref22 extending in the second direction h12.

In addition, it should be noted that the structures of the pixel driving circuits shown in FIG. 1 and FIG. 2 are merely illustrative, and the number and/or the connection relationship and/or the structure of the transistors in the pixel driving circuit may also be adjusted according to different design requirements. For example, in some embodiments of the present disclosure, the fourth transistor T4 and the fifth transistor T5 may also be provided as oxide transistors to improve the potential stability of the first node N1 and improve the flicker problem of the display panel during low-frequency operation.

In some embodiments of the present disclosure, the first signal line 21 may include any one of the data line data, the first power supply voltage line pvdd, the second power supply voltage line pvee, and the reference voltage line ref; and the second signal line 22 may include any one of the data line data, the first power supply voltage line pvdd, the second power supply voltage line pvee, and the reference voltage line ref.

In some embodiments of the present disclosure, the first signal line 21 may be provided as the first power supply voltage line pvdd, and the second signal line 22 may be provided as the data line data. In some embodiments of the present disclosure, as shown in

FIG. 1, when the first power supply voltage line pvdd is configured to include a first sub-power supply voltage line pvdd1 and a second sub-power supply voltage line pvdd2 that are electrically connected to each other, the first signal line 21 may be provided to be the first sub-power supply voltage line pvdd1 that is parallel to the data line data in the embodiments of the present disclosure.

In some embodiments of the present disclosure, the first signal line 21 may be provided as the first power supply voltage line pvdd, and the second signal line 22 may be provided as the reference voltage line ref.

In some embodiments of the present disclosure, as shown in FIG. 3, the array layer 2 further includes a planarization layer PLN. The planarization layer PLN is located on a side of the first signal line 21 and the second signal line 22 adjacent to the first electrode 321. An orthographic projection of the planarization layer PLN on a plane of the substrate 1 covers the first signal line 21 and the second signal line 22. As shown in FIG. 3, the planarization layer PLN includes a third convex B3 corresponding to the first signal line 21 and a fourth convex B4 corresponding to the second signal line 22. The first convex B1 of the first electrode 321 corresponds to the third convex B3 of the planarization layer PLN. The second convex B2 of the first electrode 321 corresponds to the fourth convex B4 of the planarization layer PLN. The arrangement of the planarization layer PLN can weaken the unevenness of the first electrode 321 caused by the arrangement of the first signal line 21 and the second signal line 22, and can further improve the brightness consistency of the first light-emitting element 3201 at different viewing angles, thereby improving the four-orientation color cast problem of the display panel.

In some embodiments of the present disclosure, as shown in FIG. 3, the first portion 211 and the second portion 221 are provided in a same layer. In some embodiments of the present disclosure, the first portion 211 and the second portion 221 may be made of a same material, and may be formed by a same patterning process. With this arrangement, on one hand, the heights of the first convex B1 and the second convex B2 in the first electrode 321 tend to be the same, thereby further improving the brightness uniformity of the first light-emitting element 3201 at different viewing angles, and on the other hand, the manufacturing process of the display panel can also be simplified.

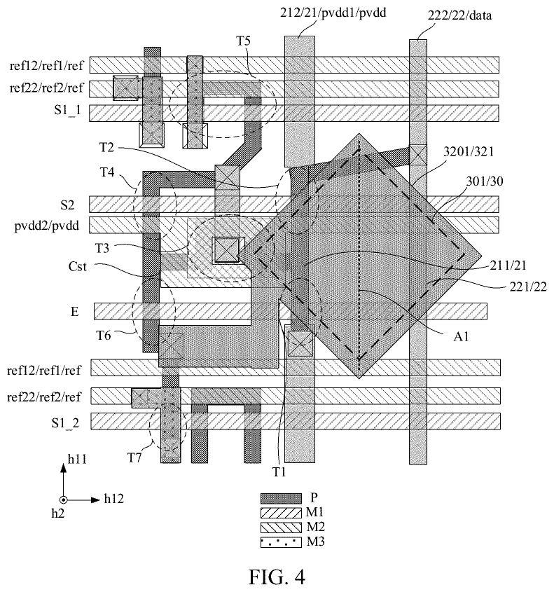

In some embodiments of the present disclosure, as shown in FIG. 1, the first signal line 21 further includes a third portion 212 electrically connected to the first portion 211, and an orthographic projection of the third portion 212 on the plane of the substrate 1 is outside he range of an orthographic projection of the first aperture 301 on the plane of the substrate 1. In some embodiments of the present disclosure, a width of the third portion 212 may be greater than or equal to a width of the first portion 211. FIG. 1 illustrates that the width of the third portion 212 is equal to the width of the first portion 211. Alternatively, as shown in FIG. 4, which is a partially enlarged schematic diagram of a display panel according to an embodiment of the present disclosure, a width of the third portion 212 is greater than a width of the first portion 211. In some embodiments of the present disclosure, by making the width of the third portion 212 greater than or equal to the width of the first portion 211, it is beneficial to reduce the resistance of the first signal line 21 while ensuring that the first portion 211 and the second portion 221 are symmetrical about the first center line A1, thereby reducing the voltage drop of the signal transmitted by the first signal line 21, and improving the brightness uniformity of the display panel at different positions.

In some embodiments of the present disclosure, the first portion 211 and the third portion 212 may be provided in a same layer. In some embodiments of the present disclosure, the first portion 211 and the third portion 212 may be made of a same material, and may be formed by a same patterning process. In some embodiments of the present disclosure, the first portion 211 and the third portion 212 may be formed of an integral structure, and do not include an interface between the first portion 211 and the third portion 212.

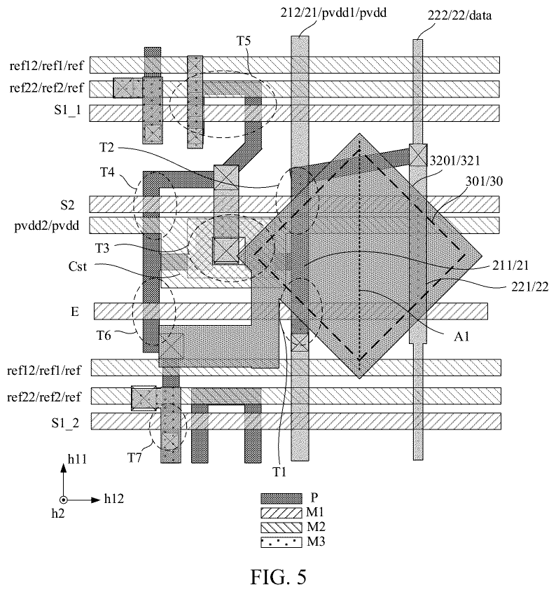

In some embodiments of the present disclosure, as shown in FIG. 1, the second signal line 22 further includes a fourth portion 222 electrically connected to the second portion 221, and an orthographic projection of the fourth portion 222 on the plane of the substrate 1 is located outside an orthographic projection of the first aperture 301 on the plane of the substrate 1. In some embodiments, the width of the fourth portion 222 is smaller than or equal to the width of the second portion 221. FIG. 1 illustrates that the width of the fourth portion 222 is equal to the width of the second portion 221. FIG. 5 is a partially enlarged schematic diagram of a display panel according to an embodiment of the present disclosure. As shown in FIG. 5, a width of the fourth portion 222 is smaller than a width of the second portion 221. In some embodiments of the present disclosure, by making the width of the second portion 221 greater than or equal to the width of the fourth portion 222, it is beneficial to reduce the resistance of the second signal line 22 while ensuring that the first portion 211 and the second portion 221 are symmetrical about the first center line A1, thereby reducing the voltage drop of the signal transmitted by the second signal line 22.

In some embodiments of the present disclosure, the second portion 221 and the fourth portion 222 are provided in a same layer. In some embodiments of the present disclosure, the second portion 221 and the fourth portion 222 may be made of a same material, and may be formed by a same patterning process. In some embodiments of the present disclosure, the second portion 221 and the fourth portion 222 may be formed of an integral structure, and do not include an interface between the second portion 221 and the fourth portion 222.

In some embodiments of the present disclosure, a width of the fourth portion 222 is smaller than or equal to a width of the third portion 212. FIG. 1 illustrates that the width of the fourth portion 222 is equal to the width of the third portion 212. FIG. 4 and FIG. 5 illustrate that the width of the fourth portion 222 is smaller than the width of the third portion 212.

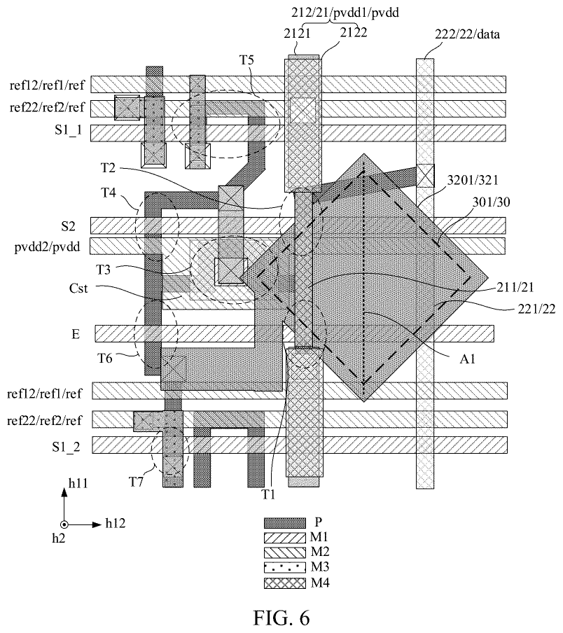

In some embodiments of the present disclosure, as shown in FIG. 6, which is a partially enlarged schematic diagram of a display panel according to an embodiment of the present disclosure, the third portion 212 includes a first sub-portion 2121 and a second sub-portion 2122 that are stacked and electrically connected. In this arrangement, the first sub-portion 2121 and the second sub-portion 2122 are connected in parallel, which can reduce the resistance of the third portion 212, thereby reducing the voltage drop of the signal in the first signal line 21 during transmission.

In some embodiments of the present disclosure, when the first portion 211 is of a single-layer structure, one of the first sub-portion 2121 and the second sub-portion 2122 may be provided in a same layer as the first portion 211. In some embodiments of the present disclosure, the first portion 211 may be configured to include two parts that are stacked and electrically connected, and one part of it and the first sub-portion 2121 are disposed in a same layer, and the another part of it and the second sub-portion 2122 are disposed in a same layer.

When the first portion 211 is configured to include two parts that are stacked and electrically connected, a part provided in a same layer as the first sub-portion 2121 is defined as a third sub-portion, and a part provided in a same layer as the second sub-portion 2122 is defined as a fourth sub-portion. In some embodiments of the present disclosure, the third sub-portion and the first sub-portion 2121 may be made of a same material, and may be formed by a same patterning process. In some embodiments of the present disclosure, the third sub-portion and the first sub-portion 2121 may be formed of an integral structure, and do not include an interface between the third sub-portion and the first sub-portion 2121. In some embodiments of the present disclosure, the fourth sub-portion and the second sub-portion 2122 may be made of a same material, and may be formed by a same patterning process. In some embodiments of the present disclosure, the fourth sub-portion and the second sub-portion 2122 may be formed of an integral structure, and do not include an interface between the fourth sub-portion and the second sub-portion 2122.

In some embodiments of the present disclosure, the array layer 2 includes a plurality of metal layers. The metal layer closest to the pixel definition layer 31 includes the first portion 211 and the second portion 221.

As shown in FIG. 1, FIG. 3, FIG. 4, and FIG. 5, the plurality of metal layers include a first metal layer M1, a second metal layer M2, and a third metal layer M3 that are sequentially provided in a direction away from the substrate 1, the third metal layer M3 is a metal layer closest to the pixel definition layer 31, and the third metal layer M3 includes the first portion 211 and the second portion 221.

As shown in FIG. 6, the plurality of metal layers includes a first metal layer M1, a second metal layer M2, a third metal layer M3, and a fourth metal layer M4 that are sequentially provided in a direction away from the substrate 1. The fourth metal layer M4 is a metal layer closest to the pixel definition layer 31. The fourth metal layer M4 includes the first portion 211 and the second portion 221. The closer the distance between the signal line and the pixel definition layer 31 is, the greater the influence on the flatness of the first electrode 321 will be. In some embodiments of the present disclosure, the first portion 211 and the second portion 221 symmetrically provided about the first center line A1 in the metal layer closest to the pixel definition layer 31, other structures capable of affecting the flatness of the first electrode 321 can be avoided from being provided in the metal layer adjacent to the pixel definition layer 31, which can ensure the brightness uniformity of the first light-emitting element 3201 at different viewing angles, thereby reducing the color cast difference of the display panel at different viewing angles.

In some embodiments of the present disclosure, as shown in FIG. 1, FIG. 4, FIG. 5 and FIG. 6, the first metal layer M1 includes a first scan line S1, a second scan line S2 and a first plate of the storage capacitor Cst. The second metal layer M2 includes a second plate of the storage capacitor Cst, a first reference voltage sub-line ref12 and a second reference voltage sub-line ref22. The third metal layer M3 includes a data line data and a first sub-power voltage line pvdd1. FIG. 1, FIG. 4, FIG. 5 and FIG. 6 each illustrate that the first portion 211 includes a data line data, and the second portion 221 includes a first sub-power supply voltage line pvdd1.

As shown in FIG. 1, FIG. 3, FIG. 4, FIG. 5 and FIG. 6, the array layer 2 further includes a semiconductor layer P, and the semiconductor layer P includes the channel of the transistor.

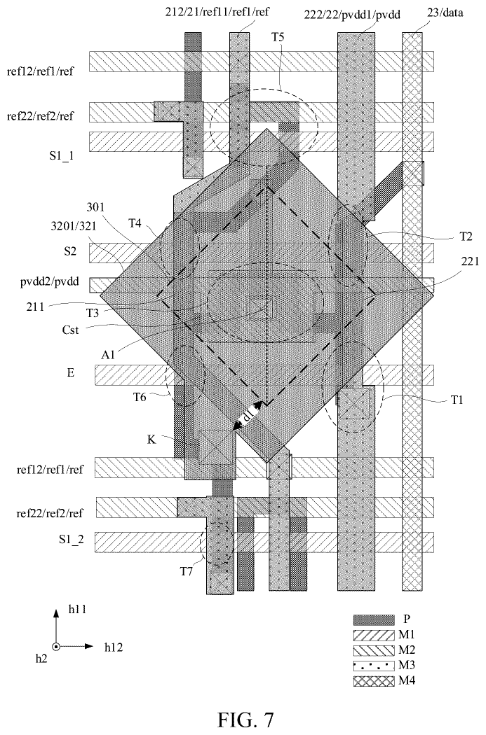

In some embodiments of the present disclosure, as shown in FIG. 7, which is a partial enlarged schematic diagram of a display panel according to an embodiment of the present disclosure, in addition to the first signal line 21 and the second signal line 22, the array layer further includes a third signal line 23. Along a direction h2 perpendicular to the plane of the substrate, the third signal line 23 at least partially does not overlap with the first aperture 301. In some embodiments of the present disclosure, by staggering the third signal line 23 and the first aperture 301, the flatness of the first electrode 321 can be prevented from being affected by the third signal line 23, thereby further improving the four-orientation color cast of the display panel.

In some embodiments of the present disclosure, as shown in FIG. 7, the first reference voltage line ref1 may be configured to include a first reference voltage sub-line ref12 extending in the second direction h12 and a third reference voltage sub-line ref11 extending in the first direction h11. The first reference voltage sub-line ref12 and the third reference voltage sub-line ref11 are electrically connected to each other. In some embodiments of the present disclosure, the first reference voltage sub-line ref12 and the third reference voltage sub-line ref11 may be located in different metal layers. FIG. 7 illustrates the first reference voltage sub-line ref12 in the second metal layer M2 and the third reference voltage sub-line ref11 in the third metal layer M3.

Based on the arrangement of FIG. 7, in some embodiments of the present disclosure, the first signal line 21 may include any one of the data line data, the first power supply voltage line pvdd, the second power supply voltage line pvee, and the reference voltage line ref. The second signal line 22 may include the other one of the data line data, the first power supply voltage line pvdd, the second power supply voltage line pvee, and the reference voltage line ref other than the first signal line 21. The third signal line 23 may include the other one of the data line data, the first power supply voltage line pvdd, the second power supply voltage line pvee, and the reference voltage line ref other than the first signal line 21 and the second signal line 22.

In some embodiments of the present disclosure, as shown in FIG. 7, the first signal line 21 may be configured to include the third reference voltage sub-line ref11, the second signal line 22 may be configured to include the first sub-power supply voltage line pvdd1, and the third signal line 23 may be configured to include the data line data.

It should be noted that, in some embodiments of the present disclosure, the second reference voltage line ref2 may also be provided to further include a fourth reference voltage sub-line extending along the first direction h11, and the fourth reference voltage sub-line is electrically connected to the second reference voltage sub-line ref21. In some embodiments of the present disclosure, the first signal line 21 may be configured to include a fourth reference voltage sub-line.

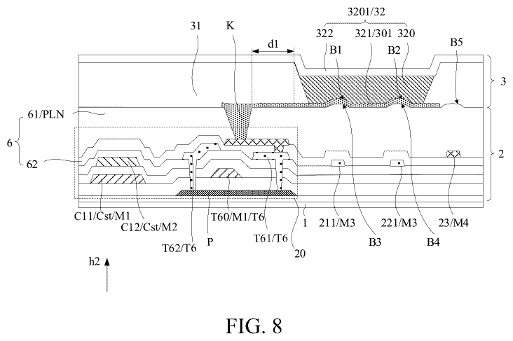

FIG. 8 is a schematic cross-sectional view of a display panel according to an embodiment of the present disclosure. Referring to FIG. 8, a part of the planarization layer PLN corresponding to the third signal line 23 forms a fifth convex B5, and along a direction h2 perpendicular to a plane of the substrate, the third signal line 23 at least partially does not overlap with the first aperture 301, so that the first electrode 321 can be located away from the fifth convex B5, thereby avoiding the flatness of the first electrode 321 from being affected by the fifth convex B5, ensuring the brightness uniformity of the first light-emitting element 3201 at different viewing angles, and reducing the color cast difference of the display panel at different viewing angles.

As shown in FIG. 8, along a direction h2 perpendicular to the plane of the substrate 1, the third signal line 23 is located on a side of the first portion 211 adjacent to the first electrode 321. The closer the distance from the first electrode 321 is, the greater the degree of influence on the flatness of the first electrode 321 is. Adopting the arrangement provided in the embodiments of the present disclosure can ensure that the structure that can affect the flatness of the first electrode 321 and that is provided in the metal layer adjacent to the first electrode 321 avoids the first electrode 321.

In some embodiments of the present disclosure, as shown in FIG. 7 and FIG. 8, the array layer includes a plurality of metal layers. In some embodiments of the present disclosure, the metal layer closest to the first electrode 321 includes a third signal line 23, and the metal layer where the third signal line 23 is located is adjacent to the metal layer where the first portion 211 is located in the direction perpendicular to the substrate. That is, the metal layer adjacent to the third signal line 23 includes the first portion 211 and the second portion 221.

FIG. 7 and FIG. 8 illustrate that the array layer 2 includes a first metal layer M1, a second metal layer M2, a third metal layer M3, and a fourth metal layer M4 sequentially arranged in a direction away from the substrate 1. The fourth metal layer M4 is a metal layer closest to the pixel definition layer 31, and the fourth metal layer M4 includes the third signal line 23. The third metal layer M3 is a metal layer adjacent to the fourth metal layer M4, and the third metal layer M3 includes the first portion 211 and the second portion 221.

In some embodiments of the present disclosure, as shown in FIG. 7, the first metal layer M1 includes a first scan line S1, a second scan line S2, and a first plate of the storage capacitor Cst. The second metal layer M2 includes a second plate of the storage capacitor Cst, a first reference voltage sub-line ref12, a second reference voltage sub-line ref22, and a second sub-power supply voltage line pvdd2. The third metal layer M3 includes a third reference voltage sub-line ref11 and a first sub-power voltage line pvdd1. The fourth metal layer M4 includes a data line data. As shown in FIG. 7, the first portion 211 includes a third reference voltage sub-line ref11, the second portion 221 includes a first sub-power supply voltage line pvdd1, and the third signal line 23 includes a data line data.

In some embodiments of the present disclosure, as shown in FIG. 3 and FIG. 8, the array layer 2 further includes a first insulation layer 6, and the pixel driving circuit 20 is located on a side of the first insulation layer 6 away from the first electrode 321. That is, the first insulation layer 6 is located between the pixel driving circuit 20 and the first electrode 321. The first insulation layer 6 includes a via hole K, and the first electrode 321 is electrically connected to the pixel driving circuit 20 through the via hole K. As shown in FIG. 2, FIG. 3 and FIG. 8, the first electrode 321 is electrically connected to the sixth transistor T6 in the pixel driving circuit 20 through the via hole K. As shown in FIG. 3 and FIG. 8, the sixth transistor T6 includes a grid electrode T60, a first electrode T61, a second electrode T62, and a channel formed by the semiconductor layer P. Along a direction h2 perpendicular to the plane of the substrate 1, the via hole K at least partially does not overlap with the first aperture 301. When manufacturing the display panel, the via hole K penetrating through the first insulation layer 6 is formed first, then the first electrode 321 is formed, a part of the first electrode 321 is filled in the via hole K, the other part of the first electrode 321 covers the surface of the first insulation layer 6 where the via hole K is not formed, and after the first electrode 321 is formed, the position corresponding to the via hole K is recessed compared with other positions, so that the first electrode 321 forms a recess. in some embodiments of the present disclosure, the via hole K does not overlap with the first aperture 301, so that the recess can be prevented from affecting the part of the first electrode 321 located in the first aperture 301, the brightness consistency of the first light-emitting element 3201 at different viewing angles can be further improved, and the color cast level of the display panel at different viewing angles tends to be consistent.

In some embodiments of the present disclosure, as shown in FIG. 3 and FIG. 8, the first insulation layer 6 includes a first sub-insulation layer 61 and a second sub-insulation layer 62. In some embodiments of the present disclosure, the first sub-insulation layer 61 includes the planarization layer PLN.

As shown in FIG. 7 and FIG. 8, along the direction parallel to the plane of the substrate 1, the distance d1 between the via hole K and the first aperture 301 satisfies: d1>7 μm, so as to ensure that the via hole K and the first aperture 301 can be completely staggered in the direction h2 perpendicular to the substrate 1.

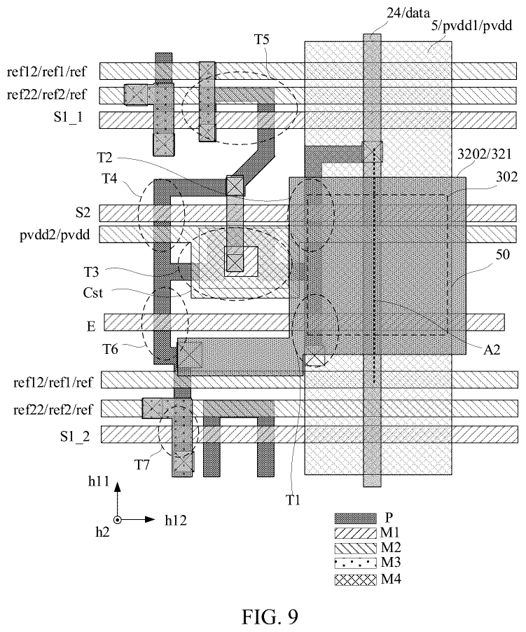

In some embodiments of the present disclosure, as shown in FIG. 9, which is a partially enlarged schematic diagram of a display panel according to an embodiment of the present disclosure, the light-emitting element 32 further includes a second light-emitting element 3202. A light-emitting color of the second light-emitting element 3202 is different from a light-emitting color of the first light-emitting element 3201. The pixel definition layer 31 has a second aperture 302 corresponding to the second light-emitting element 3202. That is, the second aperture 302 exposes at least a part of the first electrode 321 of the second light-emitting element 3202. The array layer 2 further includes a cushion layer 5. The cushion layer 5 includes an overlapping portion 50. An orthographic projection of the overlapping portion 50 on the plane of the substrate 1 is located in an orthographic projection of the second aperture 302 on the plane of the substrate 1. An area of the orthographic projection of the overlapping portion 50 on the plane of the substrate 1 is S1. An area of the second aperture 302 is S2, and in some embodiments of the present disclosure, S1≤S2. For example, 20%≤S1/S2≤100%. As shown in FIG. 9, S1=S2.

In some embodiments of the present disclosure, by providing the cushion layer 5, the flatness of the area of the first electrode 321 of the second light-emitting element 3202 overlapping with the cushion layer 5 can be improved, thereby improving the brightness consistency of the second light-emitting element 3202 at different viewing angles.

Moreover, in some embodiments of the present disclosure, the brightness consistency of the first light-emitting element 3201 at different viewing angles is improved by adopting the arrangement of making the first portion 211 and the second portion 221 symmetrical about the first center line A1, and the brightness consistency of the second light-emitting element 3202 at different viewing angles is improved by using the arrangement of providing the cushion layer 5. That is, different adjustments are respectively applied to the first light-emitting element 3201 and the second light-emitting element 3202 having different light-emitting colors, which is beneficial to better match the first light-emitting element 3201 and the second light-emitting element 3202 with white light meeting the color coordinate requirement, so as to improve the white balance of the display panel.

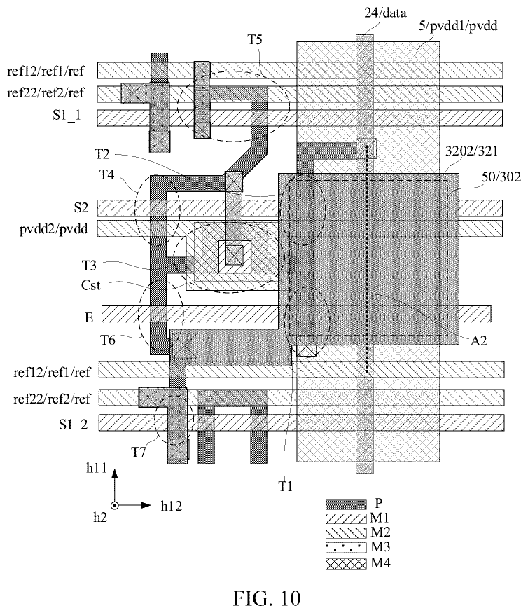

FIG. 10 is a partial enlarged schematic diagram of a display panel according to an embodiment of the present disclosure. In some embodiments of the present disclosure, as shown in FIG. 10, S1<S2. As shown in FIG. 10, an orthographic projection of the second aperture 302 on the plane of the substrate 1 includes a second center line A2, and orthographic projections of the overlapping portions 50 on the plane of the substrate 1 are symmetrical about the second center line A2. With this arrangement, the part of the second aperture 302 not provided with the cushion layer 5 may be symmetrical about the second center line A2, so that when the display panel is viewed at a large viewing angle located on both sides of the second center line A2, the brightness of the second light-emitting element 3202 tends to be consistent, and the color cast degree of the display panel at different viewing angles tends to be consistent.

In some embodiments of the present disclosure, the cushion layer 5 transmits a fixed signal. Compared with the first signal line 21 or the second signal line 22 described above, the width of the cushion layer 5 is larger. In some embodiments of the present disclosure, the cushion layer 5 is provided to transmit a fixed signal, so that a voltage drop of a corresponding signal in a transmission process can be reduced. In some embodiments of the present disclosure, the cushion layer 5 may transmit any one of the reference voltage REF, the first power supply voltage PVDD, and the second power supply voltage PVEE.

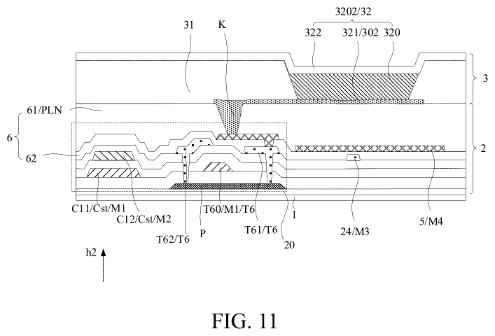

In some embodiments of the present disclosure, as shown in FIG. 11, which is a schematic cross-sectional view of a display panel according to an embodiment of the present disclosure, the array layer 2 includes a plurality of metal layers, and a metal layer closest to the pixel definition layer 31 in the plurality of metal layers includes a cushion layer 5. That is, the metal layer where the cushion layer 5 is located is the closest metal layer to the pixel defining layer 31. With this arrangement, other structures capable of affecting the flatness of the first electrode 321 can be prevented from being provided in the metal layer adjacent to the pixel definition layer 31, and the brightness uniformity of the second light-emitting element 3202 at different viewing angles can be ensured, thereby reducing the color cast difference of the display panel at different viewing angles. As shown in FIG. 11, the plurality of metal layers includes a first metal layer M1, a second metal layer M2, a third metal layer M3, and a fourth metal layer M4 that are sequentially provided in a direction away from the substrate 1, the fourth metal layer M4 is a metal layer closest to the pixel definition layer 31, and the fourth metal layer M4 includes the cushion layer 5.

In some embodiments of the present disclosure, as shown in FIG. 9, FIG. 10 and FIG. 11, the array layer 2 further includes a fourth signal line 24 located on a side of the cushion layer 5 away from the first electrode 321, and an orthographic projection of the fourth signal line 24 on a plane of the substrate 1 at least partially passes through the second center line A2. FIG. 9 and FIG. 10 illustrate the second center line A2 extending in the first direction h11. In some embodiments of the present disclosure, by making at least a part of the orthographic projection of the fourth signal line 24 on the plane of the substrate 1 pass through the second center line A2, the flatness of the part of the first electrode 321 located on both sides of the fourth signal line 24 may be substantially the same, which is beneficial to reducing the brightness difference of the second light-emitting element 3202 at different viewing angles, thereby improving the four-orientation color cast problem of the display panel and improving the display effect.

In some embodiments of the present disclosure, the metal layer where the fourth signal line 24 is located is adjacent to the metal layer where the cushion layer 5 is located, so as to avoid providing other structures that can affect the flatness of the first electrode 321 in the metal layer closer to the pixel definition layer 31, so as to ensure the brightness uniformity of the second light-emitting element 3202 at different viewing angles, thereby reducing the color cast difference of the display panel at different viewing angles. In FIG. 9, FIG. 10 and FIG. 11, the third metal layer M3 includes a fourth signal line 24. The fourth signal line 24 includes a data line data as an example.

In some embodiments of the present disclosure, the first light-emitting element 3201 includes a green light-emitting element or a blue light-emitting element. The second light-emitting element 3202 includes a red light-emitting element. The larger the proportion of the area of the uneven part of the first electrode 321 in the first electrode 321, the more serious the color cast problem caused by the uneven part of the first electrode 321 will be. In the related art, the proportion of the area of the uneven part of the first electrode 321 of the red light-emitting element in the first electrode 321 is greater than the proportion of the area of the uneven part of the first electrode 321 of the green light-emitting element in the first electrode 321, and the proportion of the area of the uneven part of the first electrode 321 of the red light-emitting element in the first electrode 321 is greater than the proportion of the area of the uneven part of the first electrode 321 of the blue light-emitting element in the first electrode 321, which results in the green light-emitting element having a lower level of color cast than the red light-emitting element, and the blue light-emitting element having a lower level of color cast than the red light-emitting element, in the relevant technology. The cushion layer 5 will have a stronger improvement for color cast than the symmetrical provided first portion 211 and the second portion 221, in some embodiments of the present disclosure, the second light-emitting element 3202 corresponding to the cushion layer 5 is a red light-emitting element, and the cushion layer 5 may be used to improve the flatness of the first electrode 321 of the red light-emitting element, so that the color cast level of the red light-emitting element with a relatively higher color cast level is reduced to match the green light-emitting element or the blue light-emitting element with a relatively lower color cast level, so that the light-emitting elements with different light-emitting colors better match the white light meeting the color coordinate requirement, thereby improving the white balance of the display panel.

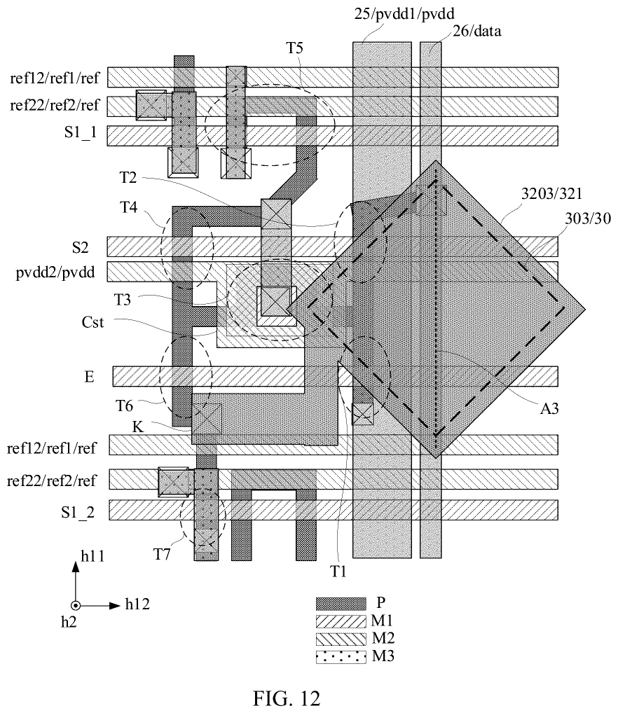

FIG. 12 is a partial enlarged schematic diagram of a display panel according to an embodiment of the present disclosure. In some embodiments of the present disclosure, as shown in FIG. 12, the light-emitting clement 32 further includes a third light-emitting clement 3203. The pixel defining layer 31 has a third aperture 303 corresponding to the third light-emitting element 3203. The signal lines further include a fifth signal line 25 and a sixth signal line 26. An orthographic projection of the fifth signal line 25 on a plane of the substrate 1 is at least partially within the range of an orthographic projection of the third aperture 303 on the plane of the substrate 1. An orthographic projection of the sixth signal line 26 on the plane of the substrate 1 is at least partially within the range of an orthographic projection of the third aperture 303 on the plane of the substrate 1. An orthographic projection of the third aperture 303 on the plane of the substrate 1 has a third center line A3. The fifth signal line 25 and the sixth signal line 26 are asymmetric about the third center line A3. In some embodiments of the present disclosure, by making the fifth signal line 25 and the sixth signal line 26 asymmetric about the third center line A3, the design freedom of the fifth signal line 25 and the sixth signal line 26 can be increased. It is beneficial to correspondingly adjusting the fifth signal line 25 and the sixth signal line 26 according to different design requirements.

In some embodiments of the present disclosure, the design requirement includes reducing a resistance of a signal line, and/or reducing a layout area of a pixel driving circuit electrically connected to the third light-emitting element 3203. For example, when the distance between the transistor electrically connected to the fifth signal line 25 in the pixel driving circuit electrically connected to the third light-emitting element 3203 and the third center line A3 is not equal to the distance between the transistor electrically connected to the sixth signal line 26 in the pixel driving circuit and the third center line A3, taking the fifth signal line 25 that includes the first sub-power supply voltage line pvdd1 shown in FIG. 12 electrically connected to the first transistor T1, and the sixth signal line 26 that includes the data line data shown in FIG. 12 electrically connected to the second transistor T2 as an example, the fifth signal line 25 and the sixth signal line 26 can have unequal distances from the third center line A3, so that the fifth signal line 25 can be designed adjacent to the first transistor TI to reduce the distance between the fifth signal line 25 and the first transistor TI, moreover, the sixth signal line 26 can be designed adjacent to the second transistor T2 to reduce the distance between the signal line 26 and the second transistor T2, so that the layout design of the pixel driving circuit electrically connected to the third light-emitting element 3203 can be more compact, so as to reduce the area of the pixel driving circuit electrically connected to the third light-emitting element 3203. And/or, in some embodiments of the present invention, the widths of the fifth signal line 25 and the sixth signal line 26 can set to be different, for example, the fifth width of the fifth signal line 25 is set to be greater than the width of the sixth signal line 26 to reduce the resistance of the fifth signal line 25, thereby reducing the voltage drop of the signal transmitted by the fifth signal line 25 during transmission.

In some embodiments of the present disclosure, the first light-emitting element 3201 may include a red light-emitting element, and the third light-emitting element 3203 may include a green light-emitting element or a blue light-emitting element. As described above, the larger the proportion of the area of the uneven part of the first electrode 321 in the total area of the first electrode 321, the more serious the color cast problem caused by the uneven part of the first electrode 321. In the related art, the proportion of the area of the uneven part of the first electrode 321 of the red light-emitting element in the first electrode 321 is greater than the proportion of the area of the uneven part of the first electrode 321 of the green light-emitting element in the first electrode 321, and the proportion of the area of the uneven part of the first electrode 321 of the red light-emitting element in the first electrode 321 is greater than the proportion of the area of the uneven part of the first electrode 321 of the blue light-emitting element in the first electrode 321. Therefore, in the related art, the green light-emitting element has a lower level of color cast than the red light-emitting element, and the blue light-emitting element has a lower level of color cast than the red light-emitting element. In some embodiments of the present disclosure, the third light-emitting element 3203 includes a green light-emitting element or a blue light-emitting element, that is, the signal line provided corresponding to the green light-emitting element is designed asymmetrical about the center line of the green light-emitting element, or the signal line provided corresponding to the blue light-emitting clement is designed asymmetrical about the center line of the blue light-emitting element, and compared with the asymmetric design of the two signal lines provided corresponding to the red light-emitting element with respect to the center line of the red light-emitting clement, while the effects such as reducing the resistance of the signal line provided corresponding to the green light-emitting element or the blue light-emitting element or reducing the layout area of the pixel driving circuit electrically connected to the green light-emitting element or the blue light-emitting element are achieved, the problem of color cast of the red light-emitting element with a relatively high color cast level can be prevented from being deteriorated. It is beneficial for the light-emitting elements with different light-emitting colors to better match the white light meeting the color coordinate requirement, thereby improving the white balance of the display panel.

In some embodiments of the present disclosure, when designing the display panel, in some embodiments of the present disclosure, the fifth signal line 25 and the sixth signal line 26 may be asymmetrically designed about the third center line A3 according to requirements such as a resistance of one of the fifth signal line 25 and the sixth signal line 26 corresponding to the third light-emitting element 3203 or a layout area of a pixel driving circuit electrically connected to the third light-emitting element 3203. Afterwards, the embodiments of the present disclosure may use the chromaticity of the third light-emitting clement 3203 under this structural design as a standard, and by providing the orthographic projection of the first portion 211 corresponding to the first light-emitting element 3201 in the plane of the substrate 1 and the orthographic projection of the second portion 221 in the plane of the substrate 1 to be symmetrical about the first center line A1, so as to make the visual color cast level of the first light-emitting element 3201 be matched with the visual color cast level of the third light-emitting element 3203, and thereby enable the light emission colors of the two to be better matched with white color satisfying the requirements for the color coordinate, and so as to achieve white balance of the display panel.

In some embodiments of the present disclosure, the fifth signal line 25 includes any one of the data line data, the first power supply voltage line pvdd, the second power supply voltage line pvee, and the reference voltage line ref. The sixth signal line 26 includes any one of a data line data, a first power supply voltage line pvdd, a second power supply voltage line pvee, and a reference voltage line ref, and the fifth signal line 25 and the sixth signal line 26 transmit different types of signal.

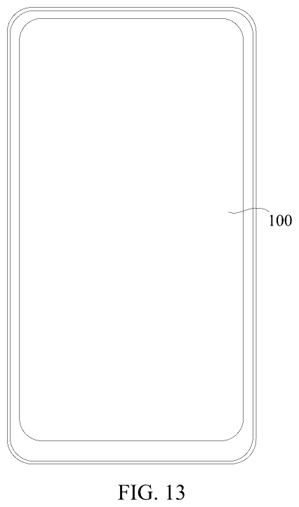

FIG. 13 is a schematic diagram of a display apparatus provided by the embodiments of the present disclosure. Based on the same inventive concept, the present disclosure further provides a display apparatus, as shown in FIG. 13, and the display apparatus includes the above display panel. The specific structure of the display panel 100 has been described in details in the above embodiments and is not repeated here. The display apparatus shown in FIG. 13 is merely for schematic illustration, and the display apparatus can be any electronic device with a display function, such as a mobile phone, a tablet computer, a notebook computer, an electronic paper book, or a television.

The above description is only a preferred embodiment of the present disclosure and is not intended to limit the present disclosure, and any modifications, equivalent substitutions, improvements and the like made within the spirit and principle of the present disclosure should be included within the scope of the present disclosure.

What is claimed is:

1. A display panel, comprising:
a substrate;
an array layer comprising a plurality of signal lines; and
a display layer located on a side of the array layer away from the substrate and comprising a pixel definition layer and light-emitting elements, wherein one of the light-emitting elements comprises a first electrode, a light-emitting layer and a second electrode that are stacked, the pixel definition layer is located on a side of the first electrode away from the substrate, the pixel definition layer has an aperture exposing at least a part of the first electrode;
wherein the light-emitting elements at least comprises a first light-emitting element, and the pixel definition layer has a first aperture corresponding to the first light-emitting element; the plurality of signal lines at least comprise a first signal line and a second signal line; the first signal line comprises a first portion, and an orthographic projection of the first portion on a plane of the substrate is within the range of the orthographic projection of the first aperture on the plane of the substrate; the second signal line includes a second portion, and an orthographic projection of the second portion on the plane of the substrate is located in the orthographic projection of the first aperture on the plane of the substrate; and
wherein the orthographic projection of the first aperture on the plane of the substrate has a first center line, and the orthographic projection of the first portion on the plane of the substrate and the orthographic projection of the second portion on the plane of the substrate are symmetrical about the first center line.

2. The display panel according to claim 1, wherein the first portion and the second portion are provided in a same layer.

3. The display panel according to claim 1, wherein the first signal line further comprises a third portion electrically connected to the first portion, and an orthographic projection of the third portion on the plane of the substrate is located outside the orthographic projection of the first aperture on the plane of the substrate; and
the third portion has a width greater than or equal to the first portion.

4. The display panel according to claim 1, wherein
the second signal line further comprises a fourth portion electrically connected to the second portion, and an orthographic projection of the fourth portion on the plane of the substrate is located outside the orthographic projection of the first aperture on the plane of the substrate; and
the fourth portion has a width smaller than or equal to the second portion.

5. The display panel according to claim 1, wherein
the first signal line further comprises a third portion electrically connected to the first portion, and an orthographic projection of the third portion on the plane of the substrate is located outside the orthographic projection of the first aperture on the plane of the substrate;
the second signal line further comprises a fourth portion electrically connected to the second portion, and an orthographic projection of the fourth portion on the plane of the substrate is located outside the orthographic projection of the first aperture on the plane of the substrate; and
the fourth portion has a width smaller than or equal to the third portion.

6. The display panel according to claim 1, wherein
the first signal line further comprises a third portion electrically connected to the first portion, and an orthographic projection of the third portion on the plane of the substrate is located outside the orthographic projection of the first aperture on the plane of the substrate; and
the third portion comprises a first sub-portion and a second sub-portion that are stacked and electrically connected to each other.

7. The display panel according to claim 1, wherein
the array layer comprises a plurality of metal layers, and along a direction perpendicular to the plane of the substrate, one metal layer of the plurality of metal layers closest to the pixel definition layer comprises the first portion and the second portion.

8. The display panel according to claim 1, wherein
the array layer further comprises a third signal line; and
along a direction perpendicular to the plane of the substrate, the third signal line at least partially does not overlap with the first aperture.

9. The display panel according to claim 8, wherein
the third signal line is located on a side of the first portion adjacent to the first electrode along a direction perpendicular to the plane of the substrate.

10. The display panel according to claim 8, wherein
the array layer comprises a plurality of metal layers, one metal layer of the plurality of metal layers where the third signal line is located is adjacent to one metal layer of the plurality of metal layers where the first portion is located in a direction perpendicular to the substrate; and
in a direction perpendicular to the plane of the substrate, one metal layer of the plurality of metal layers closest to the pixel definition layer comprises the third signal line.

11. The display panel according to claim 1, wherein
the array layer comprises a first insulation layer and a pixel driving circuit, and the pixel driving circuit is located on a side of the first insulation layer away from the first electrode;
the first insulation layer comprises a via hole, and the first electrode is electrically connected to the pixel driving circuit through the via hole; and
the via hole at least partially does not overlap with the first aperture in a direction perpendicular to the plane of the substrate.

12. The display panel according to claim 11, wherein
in a direction parallel to the plane of the substrate, a distance between the via hole and the first aperture is greater than 7 μm.

13. The display panel according to claim 1, wherein
the light-emitting elements further comprise a second light-emitting element; the pixel definition layer has a second aperture corresponding to the second light-emitting element; and
the array layer further comprises a cushion layer, the cushion layer comprises an overlapping portion, an orthographic projection of the overlapping portion on the plane of the substrate is located in an orthographic projection of the second aperture on the plane of the substrate, an area S1 of the orthographic projection of the overlapping portion on the plane of the substrate and an area S2 of the second aperture satisfy S1≤S2.

14. The display panel according to claim 13, wherein
S1<S2; and
the orthographic projection of the second aperture on the plane of the substrate comprises a second center line, and the orthographic projection of the overlapping portion on the plane of the substrate is symmetrical about the second center line.

15. The display panel according to claim 13, wherein the cushion layer transmits a fixed signal.

16. The display panel according to claim 13, wherein the array layer comprises a plurality of metal layers; and
along a direction perpendicular to the plane of the substrate, one metal layer of the plurality of metal layers closest to the pixel definition layer comprises the cushion layer.

17. The display panel according to claim 13, wherein the orthographic projection of the second aperture on the plane of the substrate comprises a second center line;
the array layer further comprises a fourth signal line located on a side of the cushion layer away from the first electrode, and an orthographic projection of the fourth signal line on the plane of the substrate at least partially passes through the second center line.

18. The display panel according to claim 13, wherein
the first light-emitting element comprises a green light-emitting element or a blue light-emitting element; and
the second light-emitting element comprises a red light-emitting element.

19. The display panel according to claim 1, wherein
the light-emitting elements further comprise a third light-emitting element;
the pixel definition layer has a third aperture corresponding to the third light-emitting element;
the signal line further comprises a fifth signal line and a sixth signal line;
an orthographic projection of the fifth signal line on the plane of the substrate is at least partially located in an orthographic projection of the third aperture on the plane of the substrate;
an orthographic projection of the sixth signal line on the plane of the substrate is at least partially located in the orthographic projection of the third aperture on the plane of the substrate; and
the orthographic projection of the third aperture on the plane of the substrate comprises a third center line, and the fifth signal line and the sixth signal line are asymmetric about the third center line.

20. A display apparatus, comprising a display panel,
wherein the display panel comprises:
a substrate;
an array layer comprising a plurality of signal lines; and
a display layer located on a side of the array layer away from the substrate and comprising a pixel definition layer and light-emitting elements, wherein one of the light-emitting elements comprises a first electrode, a light-emitting layer and a second electrode that are stacked, the pixel definition layer is located on a side of the first electrode away from the substrate, the pixel definition layer has an aperture exposing at least a part of the first electrode;
wherein the light-emitting elements at least comprise a first light-emitting element, and the pixel definition layer has a first aperture corresponding to the first light-emitting element; the plurality of signal lines at least comprise a first signal line and a second signal line; the first signal line comprises a first portion, and an orthographic projection of the first portion on the plane of the substrate is within the range of the orthographic projection of the first aperture on the plane of the substrate; the second signal line includes a second portion, and an orthographic projection of the second portion on the plane of the substrate is located in the orthographic projection of the first aperture on the plane of the substrate; and
wherein the orthographic projection of the first aperture on the plane of the substrate has a first center line, and the orthographic projection of the first portion on the plane of the substrate and the orthographic projection of the second portion on the plane of the substrate are symmetrical about the first center line.
